(19) United States
(12) Patent Application Publication
(10) Pub. No.: US 2015/0372100 A1
(43) Pub. Date: Dec. 24, 2015

(54) INTEGRATED CIRCUITS HAVING IMPROVED CONTACTS AND METHODS FOR FABRICATING SAME

(71) Applicant: GLOBALFOUNDRIES, Inc., Grand Cayman (KY)

(72) Inventors: Gerd Zschätzsch, Dresden (DE); Stefan Flachowsky, Dresden (DE); Jan Hoentschel, Dresden (DE)

(21) Appl. No.: 14/309,586

(22) Filed: Jun. 19, 2014

(51) Int. Cl. H01L 29/40; H01L 29/78; H01L 29/417

(52) U.S. Cl. CPC H01L 29/401; H01L 29/41725; H01L 29/7848

(57) ABSTRACT

Integrated circuits having improved contacts and improved methods for fabricating integrated circuits having contacts are provided. In an embodiment, a method for fabricating an integrated circuit includes providing a semiconductor substrate with a source/drain region. The method deposits an interlayer dielectric material over the semiconductor substrate. Further, the method etches the interlayer dielectric material to form a hole defining an exposed portion of the source/drain region. The method includes forming a contact forming a contact in the hole over the exposed portion of the source/drain region and forming an interconnect in the hole over the contact.

### TECHNICAL FIELD

The present disclosure generally relates to integrated circuits having improved contacts and to improved methods for fabricating integrated circuits having contacts, and more particularly relates to integrated circuits having self-aligned contacts formed over source/drain regions and methods for fabricating integrated circuits having self-aligned contacts formed over source/drain regions.

### BACKGROUND

Self-aligned silicide technology has been widely implemented in existing CMOS technology with polysilicon gates by forming silicide on both the polysilicon gates and source/drain regions in a self-aligned manner, so that the source/drain resistance and polysilicon gate resistance are reduced (from resistance of doped silicon), leading to good device performance and yield. The self-aligned silicide process consists of depositing a layer of transition metal (e.g. Ti, Co, Ni, Al, etc.) over the partially fabricated integrated circuit followed by a rapid thermal anneal (RTA). As is well-known, chemical reaction occurs between silicon and metal to form silicide, while metal contacting silicon-oxide or other non-silicon materials remains non-reacted and does not form silicide. Edges of the silicide are aligned with the edge of the underlying silicon layer.

In advanced CMOS processing, high-k metal-gate technology is the standard practice and the self-aligned silicide technology is performed on source/drain regions after polysilicon gate/spacer formation and epitaxial layer growth on source/drain regions (in gate-first flow) or after replacement gate formation (in gate-last flow). Self-aligned silicide technology is also used for non-planar integrated circuits, such as with FinFET technology, and is performed on the source/drain regions after polysilicon gate/spacer formation (gate-first flow) or after replacement gate formation (gate-last flow).

Whether used with planar or non-planar structures, conventional processes using self-aligned silicide technology can lead to yield loss in integrated circuit fabrication. Specifically, conventional processing deposits a dielectric layer over the silicide contacts, and then etches through the dielectric layer to form holes that land on the silicide contacts. The holes are then filled with conductive material to form local interconnects. Alignment of the holes with the silicide contacts can be difficult to achieve during contact hole formation. Misalignment of the contact holes with the silicide contacts leads to “contact punch-through” wherein the local interconnect formed in the contact hole lands directly on the semiconductor substrate instead of onto a silicide contact. Contact punch-through results in high contact resistance.

When self-aligned silicide technology is used in conjunction with stress regions that selectively modify channel mobility, the process typically requires formation of silicon over the stress regions. Specifically, source/drain regions are typically etched to form cavities that are filled with stress material. Then, an upper portion of the stress material is etched and replaced with a layer of undoped silicon. The self-aligned silicide process reacts a metal with the layer of undoped silicon to form a silicide contact over the stress material and aligned with the semiconductor substrate. Due to the inclusion of the layer of silicon material/silicide contact in the cavities, the amount of force exerted from the cavity is less than optimal.

Accordingly, it is desirable to provide improved integrated circuits and improved methods for fabricating integrated circuits with self-aligned contacts. In addition, it is desirable to provide integrated circuits and methods for fabricating integrated circuits that increase stress applied to channels for increased channel mobility. Furthermore, other desirable features and characteristics will become apparent from the subsequent detailed description and the appended claims, taken in conjunction with the accompanying drawings and the foregoing technical field and background.

### BRIEF SUMMARY

Integrated circuits having improved contacts and improved methods for fabricating integrated circuits having contacts are provided. In accordance with one embodiment, a method for fabricating an integrated circuit includes providing a semiconductor substrate with a source/drain region. The method deposits an interlayer dielectric material over the semiconductor substrate. Further, the method etches the interlayer dielectric material to form a hole defining an exposed portion of the source/drain region. The method includes forming a contact in the hole over the exposed portion of the source/drain region and forming an interconnect in the hole over the contact.

In another embodiment, a method for fabricating an integrated circuit includes providing a semiconductor substrate having an upper substrate surface. The method includes etching a cavity into the semiconductor substrate. The method fills the cavity with a stress material that has an upper stress surface substantially coplanar with the upper substrate surface. The method includes depositing an interlayer dielectric over the upper stress surface and upper substrate surface. The method further includes etching the interlayer dielectric material to expose a portion of the upper stress surface and forming a contact over the exposed portion of the upper stress surface.

In accordance with another embodiment, an integrated circuit is provided. The integrated circuit includes a semiconductor substrate having a source/drain region. The integrated circuit includes a contact on the source/drain region that has a first contact edge and a second contact edge. The integrated circuit further includes an interconnect structure on the contact. The interconnect structure has a first interconnect edge aligned with the first contact edge and a second interconnect edge aligned with the second contact edge.

### BRIEF DESCRIPTION OF THE DRAWINGS

Embodiments of integrated circuits having improved contacts and improved methods for fabricating integrated circuits having contacts will hereinafter be described in conjunction with the following drawing figures, wherein like numerals denote like elements, and wherein:

FIGS. 1-9 are cross-sectional views illustrating a portion of an integrated circuit and a method for fabricating the integrated circuit in accordance with various embodiments herein; and

FIG. 10 is a close-up view of a portion of the integrated circuit of FIG. 9 with structures removed for purposes of clarity.

### DETAILED DESCRIPTION

The following detailed description is merely exemplary in nature and is not intended to limit the various embodiments of the integrated circuits or the methods for fabricating integrated circuits claimed herein. Furthermore, there is no intention to be bound by any expressed or implied theory presented in the preceding technical field, background or brief summary, or in the following detailed description.

Integrated circuits and methods for fabricating integrated circuits as described herein avoid issues faced in conventional processes. For example, exemplary integrated circuits and exemplary methods for fabricating integrated circuits avoid contact punch-through during contact hole formation. In an embodiment, an interlayer dielectric material is formed over areas to be contacted, such as source/drain regions or gate structures, before contacts or contact-forming layers are formed on the areas to be contacted. Then, the dielectric material is etched to form holes exposing the areas to be contacted. After exposing the areas to be contacted, a contact formation process is performed including, for example, deposition of a silicon material and a silicide-forming material followed by a thermal anneal process. As a result, the exemplary method forms contacts in the contact holes and contact hole punch-through is avoided. Also, exemplary integrated circuits and exemplary methods for fabricating integrated circuits provide for increased or maximized stress application to channel regions under selected gate structures by filling stress region cavities with stress material. The stress material is formed with an upper surface co-planar with the upper surface of the semiconductor substrate. The exemplary contact formation process deposits silicon material and silicide-forming material over the upper surface of the stress material and not in the stress region cavity. As a result, the stress exerted by the stress region cavity may be optimized.

Turning now to FIG. 1, in an exemplary embodiment, the process of fabricating an integrated circuit 10 begins by providing a semiconductor substrate 12 with an upper surface 14 over which gate structures 16 and 17, spacers 18, and other features may be formed. The semiconductor substrate 12 is typically a silicon wafer and includes various doping configurations as is known in the art to define an N-channel FET (NFET) area over which NFET gate structure 16 is formed and a P-channel field effect transistor (PFET) area over which PFET gate structure 17 is formed. The semiconductor substrate 12 may also include other elementary semiconductor materials such as germanium. Alternatively, the semiconductor substrate 12 may include a compound semiconductor such as, silicon carbide, gallium arsenide, indium arsenide, or indium phosphide. Further, the semiconductor substrate 12 may optionally include an epitaxial layer (epi layer), may be strained for performance enhancement, and/or may include a silicon-on-insulator (SOI) structure. Further, the semiconductor substrate 12 may be formed into fin structures for use in FinFETs. The semiconductor substrate further includes isolation regions 20, such as Shallow Trench Isolation (STI), that are processed before the gate and that separate PFET active areas from NFET active areas. The detailed fabrication of STI regions 20 is well known and does not directly affect the subject matter herein.

As shown, gate structures 16 and 17 are formed overlying the semiconductor substrate 12. Each gate structure 16 and 17 can be realized as a composite structure or stack that is formed from a plurality of different layers and materials. In this regard, the gate structures 16 and 17 can be formed by conformally depositing layers of material, using photolithographic techniques to pattern the deposited layers of material, and selectively etching the patterned layers to form the desired size and shape for the gate structures 16 and 17. For example, a relatively thin layer of dielectric material (commonly referred to as the gate insulator) can be initially deposited over the semiconductor substrate 12 using, for example, a sputtering, chemical vapor deposition (CVD) or atomic layer deposition (ALD) technique. Alternatively, this gate insulator layer could be formed by growing a dielectric material, such as silicon dioxide, on exposed silicon surfaces of the semiconductor substrate 12. In certain embodiments, a gate electrode material, such as a polycrystalline silicon material or a metal material (e.g., titanium nitride, tantalum nitride, tungsten nitride, or another metal nitride) is formed overlying the gate insulator layer. For advanced CMOS technology, gate processing is typically processed by first patterning a dummy polysilicon or amorphous silicon layer in the shape of the gate, acting as a placeholder until being further removed and replaced with a metal in a damascene way. This is referred to as the Replacement Metal Gate or RMG technique

Another insulating material may then be formed overlying the gate electrode material for use as a hard mask. This insulating material (such as silicon nitride) can be deposited using, for example, a sputtering or CVD technique. This insulating material can then be photolithographically patterned as desired to form a gate etch mask for etching of the gate structures 16 and 17. The underlying gate material is anisotropically etched into the desired topology that is defined by the gate etch mask. After patterning, the insulating material may remain on the gate structures 16 and 17 as gate caps. It should be appreciated that the particular composition of the gate structures 16 and 17 and the manner in which they are formed may vary from one embodiment to another, and that the brief description of the gate stack formation is not intended to be limiting or restrictive of the recited subject matter.

In the exemplary embodiment, spacers 18 are formed around the sides of gate structures 16 and 17. The spacers 18 can be fabricated using conventional process steps such as material deposition, photolithography, and etching. In this regard, formation of the spacers 18 may begin by conformally depositing a spacer material overlying the gate structures 16 and 17 and semiconductor substrate 12. The spacer material is an appropriate insulator, such as silicon nitride, and the spacer material can be deposited in a known manner by, for example, ALD, CVD, low pressure chemical vapor deposition (LPCVD), semi-atmospheric chemical vapor deposition (SACVD), or plasma enhanced chemical vapor deposition (PECVD). Thereafter, the spacer material is anisotropically and selectively etched to define the spacers 18. In practice, the spacer material can be etched by, for example, reactive ion etching (RIE) using a suitable etching chemistry.

In FIG. 2, a stress application process is performed around the PFET gate structure 17. As shown, an anisotropic etch process, such as a reactive ion etch (RIE) may be performed so as to selectively remove a portion of the semiconductor substrate 12 to form cavities 28 in the semiconductor substrate 12 adjacent to the spacers 18 around the PFET gate structure 17. When the semiconductor substrate 12 is in the form of an SOI, the depth of the cavities 28 may be limited so as to not encroach on the buried insulating layer. As shown, a stress material 30 may be formed in the cavities 28. For example, the stress material 30 may be silicon-germanium (SiGe). In an exemplary process, the stress material 30 is epitaxially grown in the cavities 28. For example, a dielectric layer is formed over the partially fabricated integrated circuit 10, and is patterned such as by a conventional mask and lithography process to selectively expose the cavities 28. Then, epitaxial stress material 30 is selectively grown in the cavities 28 through exposure to a deposition ambient including for example, gaseous silicon sources such as silane (SiH₄), disilane (Si₂H₆), and/or trisilane (Si₃H₈), and gaseous germanium sources such as germane (GeH₄), digermane (Ge₂H₆), and/or trigermane (Ge₃H₈), and the like. As shown, the stress material 30 is formed with an upper surface 32 that is substantially co-planar with the upper surface 14 of the semiconductor substrate 12. The upper surface 32 may result from a controlled deposition process or through a recessing process, such as planarization, that removes an overburden portion of the stress material 30. While in the illustrated embodiment stress material 30 is formed only around PFET gate structure 17, it is contemplated that another stress material may be formed additionally or alternatively around NFET gate structure 16—or that no stress material be embedded in the semiconductor substrate 12.

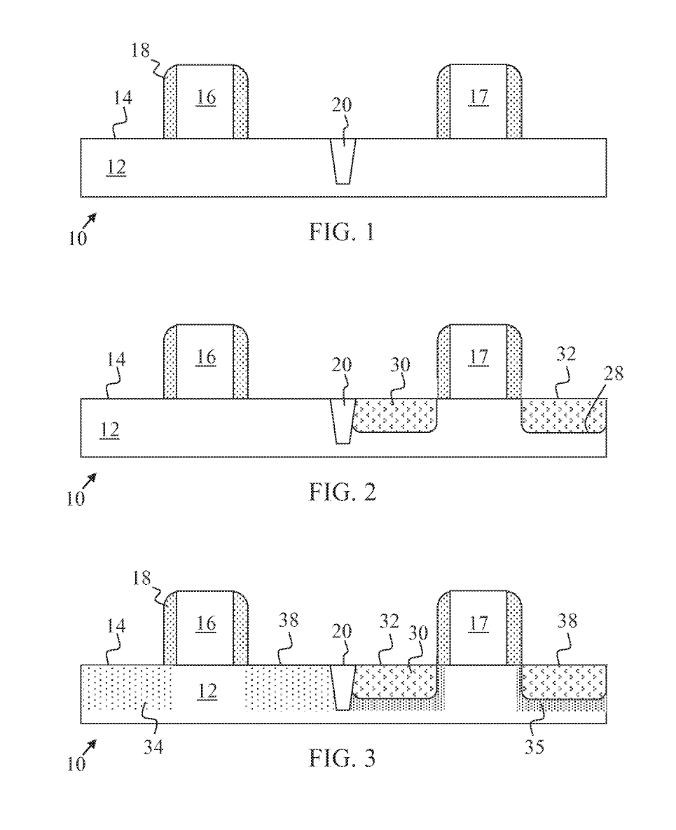

In FIG. 3, the exemplary process continues with doping of source/drain regions 34 and 35. In certain embodiment, the source/drain regions 34 and 35 may be doped before formation of the stress material 30 and/or the stress material 30 may be in-situ doped epitaxial material. As is conventional, areas of the semiconductor substrate 12 around PFET gate structures 17 are masked while areas of semiconductor substrate 12 adjacent to NFET gate structures 16 are doped by ion implantation. Further, areas of the semiconductor substrate 12 around NFET gate structures 16 are masked while areas of semiconductor substrate 12 (and stress material 30) adjacent to PFET gate structures 17 are doped by ion implantation. Ion implantation processes may include forming halo regions, extension regions and deep regions within the source/drain regions 34 and 35. As shown, the source/drain regions 34 and 35 have upper surfaces 38 that are co-planar with the upper surface 14 of the semiconductor substrate 12 and with the upper surface 32 of the stress material 30.

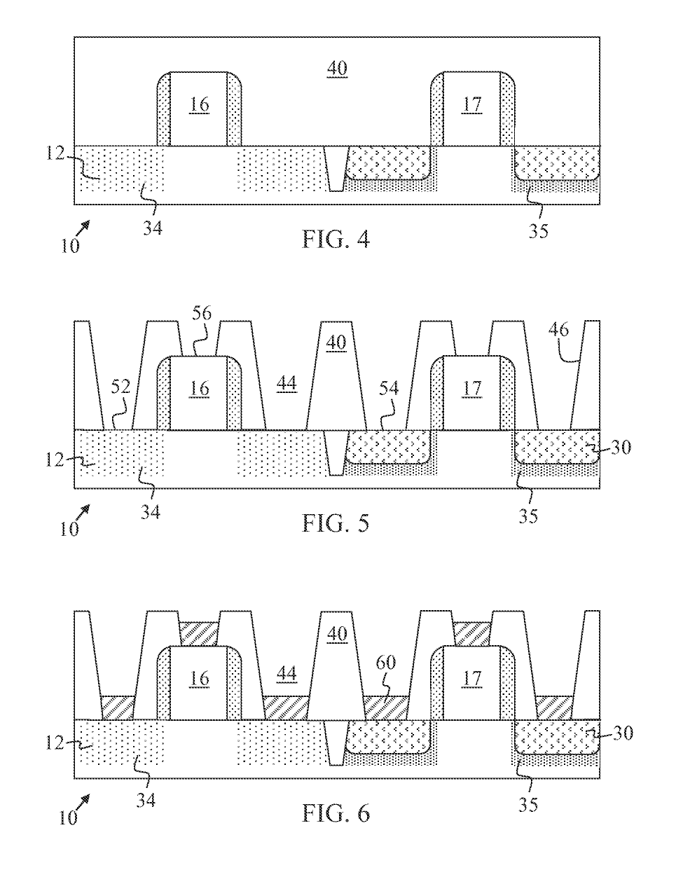

After the structure of the partially fabricated integrated circuit 10 in FIG. 3 is obtained, the method continues in FIG. 4 with depositing an interlayer dielectric (ILD) material 40 over the gate structures 16 and 17 and the source/drain regions 34 and 35. The interlayer dielectric material 40 may be a layer of low dielectric constant (low-k) insulator. “Low-k” material is generally defined as having a dielectric constant less than the dielectric constant of silicon dioxide (about 3.9). A low-k insulator can be, for example, silsesquioxane-based, fluorine or carbon-doped silica glasses, organic polymers, often fluorinated, SiOCH films, and the like. Interlayer dielectric material 40 can be deposited, for example, by spin on or chemical vapor deposition techniques, depending on the particular material being deposited. Unlike conventional processing, the interlayer dielectric material 40 is formed directly on the source/drain regions 34 and 35. Specifically, contacts or contact-forming layers are not formed on the source/drain regions 34 and 35 before the interlayer dielectric material 40 is deposited.

In FIG. 5, the interlayer dielectric material 40 is etched to form holes 44. A conventional lithography process may be used to selectively form holes 44 over gate structures 16 and 17 and over source/drain regions 34 and 35. For example, a mask may be deposited over the interlayer dielectric material 40 and patterned to expose portions of the interlayer dielectric material 40. Then, an etch process is performed to remove the exposed portions of the interlayer dielectric material 40, forming the holes 44 and exposing the gate structures 16 and 17 and source/drain regions 34 and 35. The holes 44 may be etched using a dry etching process. After the etch process, the patterned mask may be removed. As shown, the holes 44 are bound by sidewalls 46 of the interlayer dielectric material 40. The holes 44 include NFET contact holes that expose portions 52 of source/drain regions 34, PFET contact holes that expose portions 54 of source/drain regions 35 (including stress material 30), and gate holes that expose portions 56 of gate structures 16 and 17.

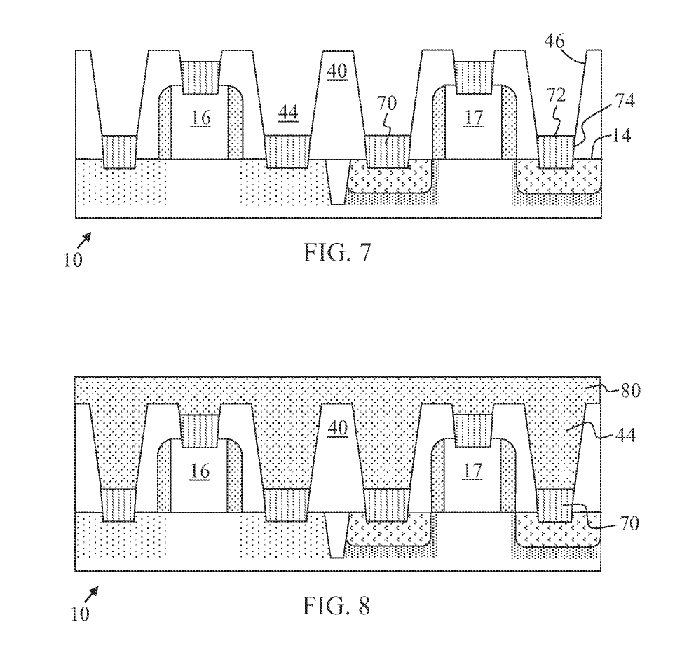

The fabrication method proceeds in FIGS. 6-7 with forming contacts to the exposed portions 52 and 54 of source/drain regions 34 and 35 and the exposed portions 56 of gate structures 16 and 17. In FIG. 6, a silicon material 60 is formed on the exposed portions 52 and 54 of source/drain regions 34 and 35 and exposed portions 56 of gate structures 16 and 17. In an exemplary embodiment, the silicon material 60 is selectively formed on the exposed portions 52, 54 and 56. When gate structures 16 and 17 and source/drain regions 34 and 35 are formed from silicon material, such as polycrystalline silicon or silicon-germanium, silicon material 60 may be selectively formed on the exposed portions 52, 54 and 56 by epitaxial growth through exposure to a deposition ambient. The silicon material 60 may be deposited to a thickness of from about 2 nanometer (nm) to about 20 nm.

In FIG. 7, a self-aligned silicidation process is performed to convert the silicon material 60 into silicide contacts 70. For example, a silicide-forming material (not shown) is deposited over the partially fabricated integrated circuit 10, including on the silicon material 60 in the holes 44. An exemplary silicide-forming material is nickel, though other silicide-forming metals may be used. Then, a thermal annealing process is performed to cause a silicidation reaction between the silicide-forming material and the silicon material 60. As a result, silicide contacts 70 are formed over the source/drain regions 34 and 35 and gate structures 16 and 17. The silicide contacts 70 are bound by the hole sidewalls 46 formed by the interlayer dielectric material 40. In other words, each silicide contact 70 has a contact edge 74 formed on a respective hole sidewall 46.

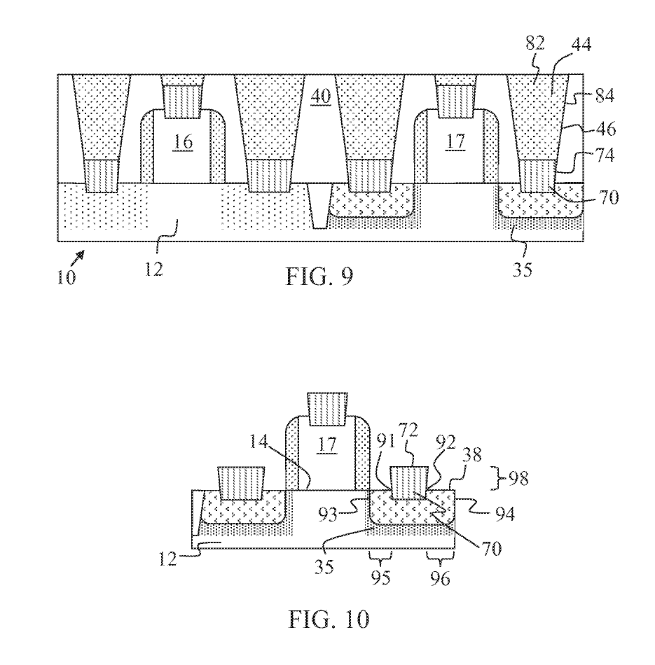

The exemplary method continues with the formation of interconnect structures over the contacts 70 in FIGS. 8-9. As shown in FIG. 8, a conductive material 80 is deposited over the partially fabricated integrated circuit 10 including in the holes 44. An exemplary conductive material 80 is copper, aluminum, or another metal suitable for processing. In FIG. 9, the conductive material 80 is planarized to the upper surface of the interlayer dielectric material 40. As a result, an interconnect 82 is formed over a respective contact 70 in each hole 44. As shown, each interconnect 82 is bounded by a hole sidewall 46. In other words, each interconnect 82 has an interconnect edge 84 formed on a respective hole sidewall 46. Further, each interconnect edge 84 is aligned with a respective contact edge 74. The partially fabricated integrated circuit 10 of FIG. 9 may be processed further to form a finished integrated circuit 10, including the deposition and patterning of additional dielectric layers and the deposition of additional conductive material layers to form a desired interconnect structure.

FIG. 10 is a close-up view of a contact 70 to a source/drain region 35 adjacent a PFET gate structure 17 of FIG. 9. with certain structures removed for clarity. The discussion related to FIG. 10 is applicable to any or all contacts 70, whether formed to source/drain regions 34, source/drain regions 35, or to gate structures 16 or 17. As shown, contact 70 has a first contact edge 91 and a second contact edge 92. Further, the exemplary source/drain region 35 has a first region edge 93 and a second region edge 94. The contact 70 is formed on, and in, the source/drain region 35 such that the first contact edge 91 is distanced from the first region edge 93 along the upper surface 38 by a portion 95 of the source/drain region 35. Further, the second contact edge 92 is distanced from the second region edge 94 along the upper surface 38 by a portion 96 of the source/drain region 35. In an exemplary embodiment, the portions 95 and 96 of the source/drain region 35 each have a width of from about 5 nm to about 30 nm (depending on the technology node and the defined pitch length). Also, contact 70 has an upper surface 72 that is distanced from the upper surface 38 of source/drain region 35 (which is co-planar with the upper surface 14 of the semiconductor substrate 12) by a contact height 98. In an exemplary embodiment, the contact height 98 is from about 5 nm to about 15 nm.

While the illustrated and described embodiments provide for formation of silicide contacts to gate structures formed from silicon material, the exemplary methods may be used during fabrication of integrated circuits with metal gates, such as replacement gates. For such embodiments, silicide contacts may be formed to the source/drain regions and not to the metal gates. Further, while embedded stress regions are formed around PFET gate structures in the illustrated embodiment, embedded stress regions may be formed around any selected gate structure, whether NFET or PFET, or may be absent from the integrated circuit.

As described herein, an embodiment of an improved integrated circuit fabrication process is implemented to form contacts to source/drain regions. Specifically, self-aligned contacts are formed on source/drain regions after deposition of interlayer dielectric material over the source/drain regions. As a result, contact punch-through is avoided. Specifically, methods described herein do not rely on landing the contact hole etch of the interlayer dielectric material on an already-formed source/drain contact. Rather, contact holes are etched into the interlayer dielectric material to expose the source/drain regions before the source/drain contacts are formed on the exposed source/drain regions. Further, both contacts and interconnects are formed in the contact holes and are bounded by the hole sidewalls. As a result, contact edges and interconnect edges are aligned.

Also, as described herein, an improved integrated circuit fabrication process is implemented to provide an increased or maximized amount of stress from embedded stress regions. Specifically, stress region cavities are formed in the semiconductor substrate and are filled with stress material. The upper surface of the stress material is formed to be co-planar with the upper surface of the semiconductor substrate. Additional silicon material supporting the formation of a silicide contact is deposited over the stress material and not in the stress region cavity. As a result, the amount of stress material in the stress region cavity is maximized.

To briefly summarize, exemplary fabrication methods described herein result in integrated circuits having source/drain contacts with reduced resistance and improved performance. Further, exemplary fabrication methods described herein result in integrated circuits having interconnect structures formed in alignment with source/drain contacts. Also, exemplary fabrication methods described herein result in integrated circuits having stress region cavities that are filled only with stress material before contacts are formed thereto.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method for fabricating an integrated circuit, the method comprising:
providing a semiconductor substrate with a source/drain region;
depositing an interlayer dielectric material over the semiconductor substrate;
etching the interlayer dielectric material to form a hole defining an exposed portion of the source/drain region;
forming a contact in the hole over the exposed portion of the source/drain region; and
forming an interconnect in the hole over the contact.

2. The method of claim 1 wherein the semiconductor substrate has an upper substrate surface, wherein the source/drain region has an upper source/drain surface co-planar with the upper substrate surface, and wherein forming the contact comprises forming the contact with an upper contact surface distanced from the upper source/drain surface and the upper substrate surface by a height, wherein the height is from about 1 nm to about 10 nm.

3. The method of claim 1 wherein forming the contact comprises:
selectively forming a silicon material in the hole over the exposed portion of the source/drain region;
depositing a silicide-forming material in the hole over the silicon material; and
annealing the silicide-forming material to form a silicide contact to the source/drain region.

4. The method of claim 1 wherein forming the contact comprises:
epitaxially growing a silicon material in the hole over the exposed portion of the source/drain region;
depositing a silicide-forming material in the hole over the silicon material; and
annealing the silicide-forming material to form a silicide contact to the source/drain region.

5. The method of claim 1 wherein:
the source/drain region has a first source/drain edge; and
forming the contact comprises positioning a portion of the source/drain region between the contact and the first source/drain edge.

6. The method of claim 1 wherein:
the source/drain region has a first source/drain edge and a second source/drain edge; and
forming the contact comprises positioning a first portion of the source/drain region between the contact and the first source/drain edge and positioning a second portion of the source/drain region between the contact and the second source/drain edge.

7. The method of claim 1 wherein providing the semiconductor substrate with the source/drain region comprises providing the semiconductor substrate with an upper substrate surface and providing the source/drain region with an upper source/drain surface co-planar with the upper substrate surface.

8. The method of claim 1 further comprising:
etching a portion of the source/drain region to form a source/drain cavity; and
filling the source/drain cavity with a stress material, wherein depositing the interlayer dielectric material comprises depositing the interlayer dielectric material over the stress material.

9. The method of claim 8 wherein:
providing the semiconductor substrate comprises providing the semiconductor substrate with an upper substrate surface; and
filling the source/drain cavity with the stress material comprises forming the stress material with an upper stress surface co-planar with the upper substrate surface.

10. The method of claim 9 wherein depositing the interlayer dielectric material comprises depositing the interlayer dielectric material over the upper stress surface.

11. The method of claim 1 wherein:
providing the semiconductor substrate comprises providing the semiconductor substrate with the source/drain region adjacent a transistor gate;
etching the interlayer dielectric material comprises forming a gate hole defining an exposed portion of the transistor gate; and
forming the contact over the exposed portion of the source/drain region comprises forming a gate contact over the exposed portion of the transistor gate.

12. The method of claim 1 wherein forming the interconnect comprises filling the hole with a conductive material.

13. The method of claim 1 wherein etching the interlayer dielectric material comprises landing an etch process on the source/drain region.

14. A method for fabricating an integrated circuit, the method comprising:
providing a semiconductor substrate having an upper substrate surface;
etching a cavity into the semiconductor substrate;
filling the cavity with a stress material, wherein the stress material has an upper stress surface substantially coplanar with the upper substrate surface;
depositing an interlayer dielectric material over the upper stress surface and upper substrate surface;
etching the interlayer dielectric material to define an exposed portion of the upper stress surface; and
forming a contact over the exposed portion of the upper stress surface.

15. The method of claim 14 wherein forming the contact comprises:
selectively forming a silicon material over the exposed portion of the upper stress surface;
depositing a silicide-forming material over the silicon material; and
annealing the silicide-forming material to form a silicide contact to the stress material.

16. The method of claim 14 wherein forming the contact comprises forming the contact with an upper contact surface distanced from the upper stress surface and upper substrate surface by a height, wherein the height is from about 1 nm to about 10 nm.

17. An integrated circuit comprising:
a semiconductor substrate having a source/drain region;
a contact on the source/drain region, wherein the contact has a first contact edge and a second contact edge; and
an interconnect structure on the contact, wherein the interconnect structure has a first interconnect edge aligned with the first contact edge and a second interconnect edge aligned with the second contact edge.

18. The integrated circuit of claim 17 wherein the semiconductor substrate has an upper substrate surface, wherein the integrated circuit further comprises a stress material formed in the source/drain region and having an upper stress surface coplanar with the upper substrate surface.

19. The integrated circuit of claim 17 wherein the semiconductor substrate has an upper substrate surface, and wherein the contact has an upper contact surface distanced from the upper stress surface and the upper substrate surface by a height from about 1 nm to about 10 nm.

20. The integrated circuit of claim 17 wherein:
the source/drain region has a first source/drain edge and a second source/drain edge;
a first portion of the source/drain region is located between the contact and the first source/drain edge; and
a second portion of the source/drain region is located between the contact and the second source/drain edge.
